(19) United States
(12) Patent Application Publication
(10) Pub. No.: US 2017/0131331 A1
(43) Pub. Date: May 11, 2017

(54) SYSTEM AND METHOD FOR DETERMINING THE POWER OF A PLURALITY OF ELECTRICAL PRODUCERS AND CONSUMERS WHICH ARE OPERATED IN A NETWORK AS A VIRTUAL POWER PLANT

(71) Applicant: LICHTBLICK SE, Hamburg (DE)

(72) Inventors: Stefan STORACE, Hamburg (DE); Martin RUMMENIE, Hamburg (DE); Sebastian KÜHNER, Hamburg (DE)

(73) Assignee: LICHTBLICK SE, Hamburg (DE)

(21) Appl. No.: 15/322,529

(22) PCT Filed: Jul. 7, 2015
(86) PCT No.: PCT/EP2015/001377

§ 371 Date: Dec. 28, 2016

(30) Foreign Application Priority Data
Jul. 7, 2014 (DE) 10 2014 009954.7

(51) Int. Cl. G01R 21/133; H02J 3/14

(52) U.S. Cl. CPC G01R 21/133; H02J 3/14

(57) ABSTRACT

A system and corresponding method, in order to determine in a real-time manner the power of a plurality of decentralized technical units, which—are spatially distributed in order to generate and/or store and/or consume electrical energy and which—are connected to a power supply network in order to feed in and/or draw electrical energy and which—are connected to a control center by means of a communication connection in order to control the operation of the technical units, is characterized by—a data memory in the control center, which data memory is designed store a power value or a plurality of different power values for each of the technical units, and by—a trigger signal transmitter for each of the technical units, which is designed, in the case of each state change of the technical unit in question between the power value and zero or between the power value and another of the power values, to send a trigger signal, which signals the state change, to the control center, and by—a computer in the control center, which computer is designed to calculate the instantaneous power of at least one technical unit that is in operation from the stored power values in accordance with the trigger signals.

The invention relates to a system and a method for the up-to-date determination of the power, particularly the total power, of multiple technical units which are spatially distributed in a decentralized manner to generate and/or consume electrical energy, which are connected to a power supply network to supply or remove electrical energy, and which are connected to a control center via a communication link for the purpose of operation control.

As is known, power plants supply electrical energy to supply networks for the purpose of establishing an energy supply, wherein spatially distributed consumers are connected to said supply r networks. In recent years, the degree of miniaturization and decentralization in this field has greatly increased: it is no longer the case that only central power plants which are independent of the location of energy consumption are operated. Rather there are more and more technical units being placed locally near consumers, which supply electrical energy to the network, on the one hand, and on the other hand remove electrical energy from the same. These can be, for example, solar cells which supply electricity to the consumers and then either store excess electricity locally in batteries or feed the same into the supply network—as well as local biogas plants or generators which are operated, by way of example, with diesel or gas and are also used to provide heat (for example, cogeneration units).

One way of operating these decentralized electrical units economically results from a form of organization which is often (and hereinafter) referred to as a “virtual power plant”: The intelligence of the virtual power plant controls the electrical units in the framework of existing degrees of freedom. In this approach, certain restrictions of the units must be taken into account (for example, ensuring the supply of heat, in the case of cogeneration units). Among other things, for this purpose, the electrical units are communicatively connected to a control center via a communication link, such as a data line. Electrical units in the present context may be (as already mentioned in part), by way of example, cogeneration units, photovoltaic systems, batteries (including mobile batteries installed, for example, in electrically-driven vehicles, e.g. connected for local charging), heat pumps, storage heaters, wind turbines or emergency generators.

For example, in order to efficiently utilize the electrical energy produced non-centrally and locally in this manner, it is important for the operator to know as precisely as possible the parameters, and in particular also the total amount of energy currently being supplied to and/or consumed from the power network by “his” technical units. This is particularly relevant in the control power market, in which, until now, measured values from each of the technical units were required to be transmitted to the control center via the communication links in 1-second-intervals—and, for this purpose, measurement in 1-second-intervals of the required values, such as the feed-in power, and provision of the same for transmission was required.

The problem addressed by the present invention is that of creating a system and a method with improved efficiency for the up-to-date determination of the power, and in particular the total power, of multiple technical units which are spatially distributed to generate, store, or consume electrical energy, which are connected to a power supply network, and which are connected to a control center via a communication link for the purpose of operation control. This problem is addressed by a system having the features of claim 1 and by a method having the features of claim 2. Preferred embodiments are specified in the dependent claims.

The system and method according to the invention focus on the up-to-date determination of the power, and in particular the total power, of multiple technical units. The technical units are spatially distributed to generate and/or store and/or consume electrical energy. The technical units are connected to a power supply network for the purpose of supplying or removing electrical energy. In order to control operation, the technical units are connected to a control center via a communication link.

According to the invention, a power value which can be expected from the technical unit and which has previously been determined is stored in the method in a data memory in the control center for each of the technical units. A preferred method according to the invention for this preliminary determination is described below. In order to determine the power, and in particular the total power, of the technical units, a trigger signal generator of each technical unit transmits a signal to the control center each time a previously defined operating state changes in a technical unit. A computer in the control center then calculates the (particularly updated) instantaneous total power of the technical units in operation according to the trigger signals, from the stored power values, by accordingly taking into account the power value of a technical unit which changes its operating point in a manner which can be detected from the trigger signal, when calculating the total power value.

Accordingly, the system according to the invention comprises a data memory in the control center, which is equipped to store a power value (which is previously determined and is expected from the technical unit) for each of the technical units. A trigger signal generator is assigned to each of the technical units of the system according to the invention, and is configured to send a signal to the control center upon every state change in the respective technical unit. And a computer, preferably in the control center of the system according to the invention, is configured to calculate the instantaneous total power of the technical units in operation from the stored power values, according to the trigger signals.

The objective is therefore particularly that of up-to-date determination of the total power of a pool of technical units, without the availability of current meter data. The total power in this case will correspond to the sum of the powers of each individual system, and thereby lie within the measurement accuracy of calibrated meters.

The advantages of this invention are as follows: Cost savings resulting from no longer needed second-counter equipment for each system. Measured power data need no longer be transmitted every second. As a result, the data volume is considerably reduced on the transmission path, as is the demand for data management in the control center, which also ultimately leads to cost savings. Higher power is made possible by lower volume of data, without a resulting loss of measurement accuracy.

The basic principle is that, because the state of each local technical unit is determined in a decentralized manner, an associated power level is determined. It is possible to significantly reduce the electronic communication complexity due to the small number of state changes of the technical units (e.g. the change from “system ON” to “system OFF”). The fundamental principle is that the power of the relevant technical unit only changes significantly when there is a state change, and a power can be uniquely assigned to each state. The technical units immediately and automatically report each change of state (e.g. operating/not operating) to the control center. From the sum signal of these states it is possible to calculate the up-to date total power furnished. If the method is used in the context of furnishing secondary control power, the amount of secondary control power results from the total power minus the power sold on the spot market.

Secondary control power (SCP) currently has a weekly tender period, so that participation in the SCP market means that the SCP retailer must offer and maintain the offered and/or contracted power over an entire week. The week is divided in this case into an High Tariff (HT) period (weekdays 08:00-20:00) and an Low Tariff (LT) period (weekdays 20:00-08:00 and Saturdays, Sundays and holidays 00:00-24:00). A differentiation is also made between positive (supply or load reduction) and negative SCP (decreased feed or load increase). Regardless of the SCP offer, the electrical work generated or consumed without a SCP request must be sold and/or distributed. This can be done on the so-called spot market, or via DayAhead or Intraday, by way of example. If a positive SCP request is received by a supplier with a cogeneration unit (CU) as a technical unit, the supplier then increases his supply power to the requested SCP amount within 5 minutes at the latest, and thus accordingly generates more than the power originally sold on the spot market. The difference between the (state-dependent) total energy and the energy sold on the spot market energy then describes the SCP and/or SCW (secondary control work) produced.

It is hereby once again emphasized as a particular advantage of the invention that it is no longer necessary as before to continuously (usually every second) measure the instantaneous power of the technical units of the system, or “pool”, and to continuously transmit the same in 1-second-intervals from each individual technical unit to the control center. Rather, it is sufficient to take into account, in the calculation of the total power value of the pool, the transmission of the state trigger signal (only at the time of the state change of the technical unit) and its monitoring and processing in the control center, specifically the previously determined power value of the technical unit detected by the trigger signal as ‘on’.

The previously determined power value can be checked centrally (or detected for the first time)—and preferably in a slower time cycle, such as every quarter-hour, for example—by saving the work output of every technical unit (locally) every quarter hour (the work output of every technical unit is typically measured, for example, by local “current meters”, without much effort, anyway). If at this point, for example, the quarter-hour trigger signal has been received twice since the last ON trigger signal from the cogeneration unit in question, without an interim OFF trigger signal, the average power of this cogeneration unit can be calculated by querying its locally stored last quarter-hour work output value, by utilizing the fact that the work output value need only be divided by the duration of this work output unit—15 minutes in the example.

The invention not only makes it possible to determine the up-to-date total power, but also enables an operation control of the “pool” of technical units. The technical units are controlled within the operational control. The objective of the control is a total power target value. To achieve this, technical units are turned on or off, or their power output or consumption is varied.

These and other advantages and features of the invention will be further described in the following illustration of an embodiment of the invention, wherein:

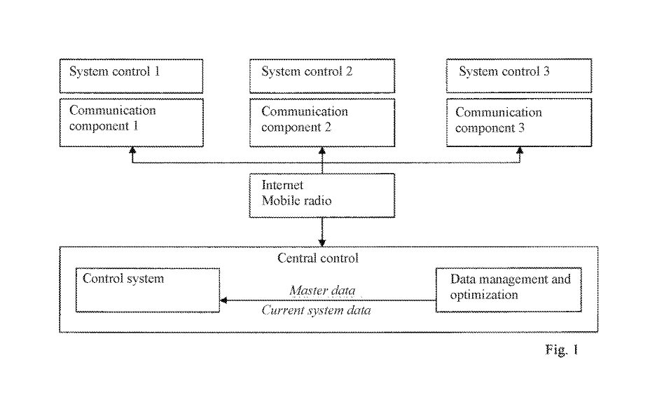

FIG. 1 shows a schematic of a system according to the invention in which the method according to the invention is carried out;

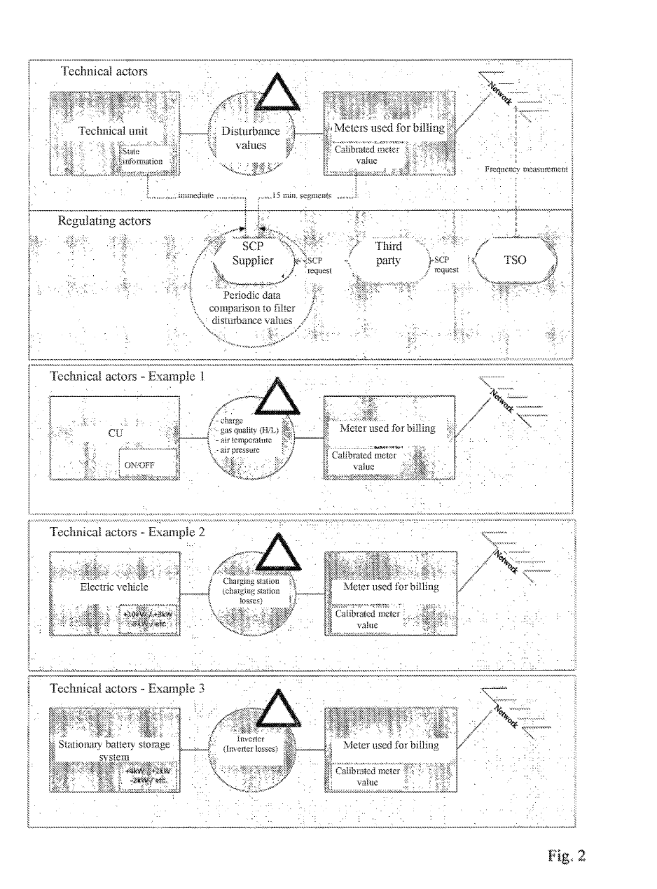

FIG. 2 shows a schematic representation of the system and method according to the invention for a condition-dependent determination of power.

According to FIG. 1, the system control of each local electrical unit (e.g. CUs 1 to 3) relays to the control center, via the respective communication component, the following data required for the determination of power, by way of example:
time,
operating state, meter data (e.g. work output of the CU in the last quarter hour),
malfunctions.

The communication component is the link between the local control system and the central control system. The data is sent both to the data management unit and to the control system.

The control system is utilized in the control process, and also in the determination of the state-dependent power output. The control system regularly retrieves updated data from the data management system.

The data management unit includes master and dynamic data of the systems. The optimization calculates in advance an optimized operation mode of the systems, drawing on master and dynamic data in the process.

Every change of state of a technical unit is stored on the database end. The expected “average” power is established using the changes of state—specifically, by way of example, using the last three complete operation blocks within the last four days. An operation block includes the period between the “on” state and the subsequent state (other than “on”).

The determination of the average power is dependent on whether and how many relevant operation blocks were determined. For each identified relevant operation block, the corresponding power is determined. The determination is made using the following formula:

Power=work/(t_{OperationBlockEnd}−t_{OperationBlockStart})

| Value | Assignment |
|---|---|
| t_{OperationBlockStart} | Time of the start of the |
| | operation block (time of the |
| | “on” state) |
| t_{OperationBlockEnd} | Time of the end of the |
| | operation block (time of the |
| | state which follows the “on” |
| | state) |
| Work | Sum of the work generated |
| | within the operation block |

If there is no determined power value, the nominal power according to specification is taken as the average value of the—by way of example—CU (e.g. for new installations with no existing state values).

FIG. 2 is an outline of the system and method according to the invention for the state-dependent determination of power.

The outlined example focuses on participation in an SCP market, and represents the general context of this example. The example also illustrates the transfer of the concept to various technical actors which can be used in such a case.

In the present context, it is possible to distinguish between regulating actors, such as transmission system operators (TSOs), optionally a third party as well as the SCP suppliers, and technical actors such as the technical unit itself (e.g. a CU or battery), a meter used for billing, and disturbance values which influence the SCP.

The TSO has the task of keeping the power network stable, and requests positive or negative SCP according to the demand in the network. The supplier receives up-to-date information, via the state-based power determination, on the power of his pool of decentralized technical units, and can visualize this against the background of the TSO, and also use this for a spontaneous SCP request by the ISO for the purpose of control or regulation.

For optimization purposes, the provider can align the state information over a larger time interval, for example, with the information of a calibrated load profile meter (power detection usually in ¼ h segments), and can draw conclusions with this information regarding effects of various interference values, as well as take this information into account as part of a state-based power determination to further improve the quality of the power-based power determination. The conditions defined in advance according to the invention for the power determination can be adapted and defined according to the technology used (technical unit).

### EXAMPLE

CU: “ON state” means (average) power at full delivery, e.g. 20 kW, and “OFF state” means 0 kW;
Battery: charging states are first divided into steps of 2 kW (power intervals) and transmitted to the supplier as states according to this pattern: −4, −2, 0, +2, +4 kW. As soon as the state of charge exceeds one of these limits (“the battery changes state”), a trigger signal is sent to the supplier (the control center)
Electric vehicle: as per the battery.

The reference points for each state can be determined in very different ways in this case. If a cogeneration unit has, by way of example, three distinct operating points, such as 0%, 50% and 100% power, these can likewise be used as states (power values)—just as a control logic in the battery management system of an electric vehicle, for example, can be used for generating trigger signals to define and report that a change from one of the power intervals to another (a state change) has occurred.

1. A system for the up-to-date determination of the power of multiple decentralized technical units which
are spatially distributed to generate and/or store and/or consume electrical energy, and which
are connected to a power supply network to supply and/or remove electrical energy, and which
are connected to a control center via a communication link for the purpose of controlling their operation,
characterized by
a data memory in the control center which is configured to store a power value, or multiple different power values for each of the technical units, and by
a trigger signal generator at each of the technical units, which is configured to send, to the control center, upon every state change in the respective technical unit between the power value and zero or between the power value and another power value, a trigger signal which signals the state change, and by
a computer in the control center which is configured to calculate from the stored power values, according to the trigger signals, the instantaneous total power of at least one technical unit in operation.

2. The system according to claim 1, characterized in that
the trigger signal generator at each of the technical units is configured to, upon every state change of the respective technical unit between a power interval and zero or between a power interval and another power interval, send a trigger signal which signals the state change to the control center, and in that
the computer in the control center is configured to calculate the instantaneous power of at least one technical unit in operation, from the stored power values which are each assigned to a power interval, according to the trigger signals.

3. A method for the up-to-date determination of the power of multiple decentralized technical units which
are spatially distributed to generate and/or store and/or consume electrical energy, and which
are connected to a power supply network to supply and/or remove electrical energy, and which
are connected to a control center to control their operation via a communication link,
characterized in that
a power value or multiple, different power values is or are stored in a data memory in the control center for each of the technical units, and in that
a trigger signal generator located at each of the technical units sends to the control center, upon every state change in the respective technical unit between the power value and another power value, a trigger signal which signals the state change, and in that
a computer in the control center calculates, from the stored power values, according to the trigger signals, the instantaneous power of at least one technical unit in operation.

4. The method according to claim 3, characterized in that
the trigger signal generator at each of the technical units, upon every state change of the respective technical unit between a power interval and zero or between a power interval and another power interval, sends a trigger signal which signals the state change to the control center, and in that
the computer in the control center calculates the instantaneous power of at least one technical unit in operation, from the stored power values which are each assigned to a power interval, according to the trigger signals.
